(19) United States
(12) Patent Application Publication
(10) Pub. No.: US 2003/0011078 A1
(43) Pub. Date: Jan. 16, 2003

(54) Semiconductor module and producing method therefor

(75) Inventors: Ryuzo Fukao, Ibaraki-ken (JP); Koji Yamaguchi, Ibaraki-ken (JP); Susumu Imai, Toride-shi (JP); Yuichi Sukegawa, Ibaraki-ken (JP)

Correspondence Address: BIRCH STEWART KOLASCH & BIRCH, PO BOX 747, FALLS CHURCH, VA, 22040-0747, US

(73) Assignee: Hitachi Maxell, Ltd.

(21) Appl. No.: 10/244,738

(22) Filed: Sep. 17, 2002

Related U.S. Application Data
(63) Continuation of application No. 09/386,137, filed on Aug. 31, 1999, now abandoned.

(30) Foreign Application Priority Data
Sep. 2, 1998 (JP) 10-248520
Mar. 8, 1999 (JP) 11-060481

(51) Int. Cl. H01L 23/28

(52) U.S. Cl. 257/787

(57) ABSTRACT

A semiconductor module comprises,

an IC chip including an electric circuit and an electrically conductive terminal surface area connected electrically to the electric circuit, an electrically conductive member fixed onto the terminal surface area with an electrical conductivity between the electrically conductive member and the terminal surface area, and a resin adhering to a part of the electrically conductive member and to a part of the IC chip, or

an alternative IC chip including an electric circuit and an antenna coil connected electrically to each other, and a resin adhering to at least a part of the alternative IC chip, wherein the alternative IC chip includes first and second surfaces opposite to each other in a thickness direction of the alternative IC chip, the antenna coil is juxtaposed with the electric circuit in the thickness direction and extends substantially along an imaginary plane parallel to the first and second surfaces, a distance between the antenna coil and the first surface is smaller than a distance between the antenna coil and the second surface in the thickness direction.

### BACKGROUND OF THE INVENTION AND RELATED ART STATEMENT

The present invention relates to a semiconductor module including an IC (integrated circuit semiconductor) chip, and a producing method therefor.

JP-A-9-131986 discloses that an IC chip is treated by wet process during a dicing process from a substrate to the chip, so that a chipping and crack of the IC chip are restrained from being generated to increase an impact strength of the chip.

### OBJECT AND SUMMARY OF THE INVENTION

An object of the present invention is to provide a significantly thin semiconductor IC chip module with a high resistance against being broken, and a producing method therefor.

According to the present invention, a semiconductor module comprises,

an IC chip including an electric circuit and an electrically conductive terminal surface area connected electrically to the electric circuit, an electrically conductive member fixed onto the terminal surface area with an electrical conductivity between the electrically conductive member and the terminal surface area, and a resin adhering to a part of the electrically conductive member and to a part of the IC chip.

Since the (monolithic) resin adheres to both of the part of the electrically conductive member and the part of the IC chip, a joint between the electrically conductive member and the IC chip is reinforced by the resin, and is restrained from being broken if a bending force is applied to the combined electrically conductive member and IC chip.

According to the present invention, a semiconductor module comprises, an IC chip including or receiving therein an electric circuit and an antenna coil connected electrically to each other, the electric circuit and the antenna coil juxtaposed with each other in the thickness direction of the IC chip, and a resin adhering to at least a part of the IC chip, wherein the IC chip includes first and second surfaces opposite to each other in a thickness direction of the IC chip, the antenna coil extends substantially along an imaginary plane parallel to the first and second surfaces, a distance between the antenna coil and the first surface is smaller than a distance between the antenna coil and the second surface in the thickness direction. Since the antenna coil is received in the IC chip or printed on the IC chip without the electrically conductive member between the antenna coil and the IC chip, a thickness of the semiconductor module is kept small while a breakage of the semiconductor module is restrained.

The IC chip includes first and second surfaces opposite to each other in a thickness direction of the IC chip and a third surface extending between the first and second surfaces, the first surface includes the terminal surface area, and the part of the electrically conductive member extends along a part of the first surface. The second surface includes a peripheral area and a central area surrounded by the peripheral area. The semiconductor module may further comprise an antenna member fixed onto the electrically conductive member with an electrical conductivity between the antenna member and the electrically conductive member. A casing may receive therein the IC chip, the electrically conductive member and the resin.

If the resin is prevented from adhering to at least a part of the second surface, a thickness of the semiconductor module is kept significantly small while strength of the joint is kept sufficiently large.

If the resin adheres to at least a part of the peripheral area at which area cracks and/or chippings exist at a significantly high probability or are generated by dicing process for dividing a semiconductor substrate into the IC chips, the resin reinforces the at least a part of the peripheral area to restrain the IC chip effectively. If the resin adheres to at least a part of the third surface to extend monolithically between the part of the electrically conductive member and the at least a part of the peripheral area, both of the joint and the peripheral area, that is, the most important areas for restraining a breakage of the semiconductor module are reinforced effectively by the resin.

If the resin adheres to the at least a part of the peripheral area and is prevented from adhering to the central area, a rigidity of the IC chip against a bending and/or twisting force is kept small or a bending and/or twisting flexibility of the IC chip is kept large while the at least a part of the peripheral area at which the cracks and/or chippings exist at the significantly high probability is effectively reinforced.

It is preferable for a modulus of longitudinal elasticity of the antenna member to be smaller than a modulus of longitudinal elasticity of the electrically conductive member, for restraining an impact force from being applied to the electrically conductive member and/or the joint from the antenna member and/or for absorbing the impact force at the antenna member.

When the electrically conductive member includes first and second sides opposite to each other in a thickness direction of the IC chip and the second side faces to the IC chip, it is preferable for the antenna member to be fixed onto the second side for minimizing a thickness of the semiconductor module.

If the resin is prevented from adhering to the electrically conductive member monolithically from the terminal surface area to the antenna member, an elasticity of each of the antenna member and a part of the electrically conductive member is utilized effectively for absorbing the impact force from the antenna member or restraining the impact force from being transmitted to the IC chip from the antenna member through the resin.

If the electrically conductive member juts out with respect to the antenna member in both directions opposite to each other and perpendicular to a longitudinal direction of the antenna member and/of if the antenna member juts out with respect to the electrically conductive member in both directions opposite to each other and perpendicular to a longitudinal direction of the electrically conductive member, a stress concentration at a joint between the antenna member and the electrically conductive member is decreased.

It is preferable for a modulus of longitudinal elasticity of the casing to be smaller than a modulus of longitudinal elasticity of the resin, for restraining an impact force from being applied to the electrically conductive member and/or the joint from the casing, and/or for absorbing the impact force at the casing.

It is preferable for the electrically conductive member to extend substantially straight between the antenna member and the terminal surface area, for restraining a stress concentration on the electrically conductive member.

The resin may adhere to the whole of the second surface to strengthen the IC chip. The casing may be fixed onto at least a part of the second surface while the resin is prevented from existing between the casing and the at least a part of the second surface, so that a thickness of the semiconductor module is kept small while the joint is reinforced effectively.

If the resin adheres to the at least a part of the third surface to extend monolithically from the first surface to the at least a part of the peripheral area, a corner between the at least a part of the third surface and the peripheral area at which corner the chipping and/or crack exists is reinforced effectively.

If the casing receiving therein the IC chip and the resin is fixed onto at least a part of the second surface while the resin is prevented from existing between the casing and the at least a part of the second surface, a thickness of the semiconductor module is kept small while the IC chip is reinforces by the resin.

The resin may be prevented from adhering to at least a part of the first surface. A thickness of the resin on the second surface is preferably not less than 10 μm and not more than a thickness of the IC chip. A thickness of the semiconductor module is preferably not more than 0.5 mm. The casing may include an adhesive layer adhering to the resin and a cover sheet adhered to the resin through the adhesive layer. The adhesive layer may include nonwoven fabric or the nonwoven fabric may be impregnated with the adhesive to form the adhesive layer.

According to the present invention, a method for producing a semiconductor module, comprises the steps of:

fixing an IC chip onto an electrically conductive member,

supplying a resin onto a joint portion between the IC chip and the electrically conductive member, and subsequently curing the resin,

removing a part of the electrically conductive member from the combined IC chip and electrically conductive member,

fixing an antenna coil onto a remainder part of the electrically conductive member of the combined IC chip and electrically conductive member, and

mounting the combined antenna coil, IC chip and electrically conductive member into a casing.

The mounting step may include:

arranging the combined antenna coil, IC chip and electrically conductive member between two nonwoven fabrics of a pair, and

arranging the pair of nonwoven fabrics between which the combined antenna coil, IC chip and electrically conductive member are arranged, between two cover sheets with an adhesive between each of the nonwoven fabrics and each of the two cover sheets facing to each other, and

compressing and heating the two cover sheets between which the pair of nonwoven fabrics is arranged, to adhere the cover sheets to the nonwoven fabrics through the adhesive.

The mounting step may include:

arranging the combined antenna coil, IC chip and electrically conductive member on a cover sheet with an adhesive between the combined antenna coil, IC chip and electrically conductive member and the cover sheet,

covering the combined antenna coil, IC chip and electrically conductive member with another cover sheet to be arranged between the cover sheets, and

compressing and heating the cover sheets between which the combined antenna coil, IC chip and electrically conductive member are arranged, to adhere the cover sheets to the combined antenna coil, IC chip and electrically conductive member through the adhesive.

According to the present invention, a method for producing a semiconductor module, comprises the steps of:

arranging an IC chip including an antenna coil and covered by a resin, between nonwoven fabrics of a pair, and

arranging the pair of nonwoven fabrics between which the IC chip is arranged, between two cover sheets with an adhesive between each of the nonwoven fabrics and each of the two cover sheets facing to each other, and

compressing and heating the two cover sheets between which the pair of nonwoven fabrics is arranged, to adhere the cover sheets to the nonwoven fabrics through the adhesive.

According to the present invention, a method for producing a semiconductor module, comprises the steps of:

arranging an IC chip including an antenna coil and covered by a resin, on a cover sheet with an adhesive between the IC chip and the cover sheet,

covering the IC chip with another cover sheet to be arranged between the cover sheets, and

compressing and heating the cover sheets between which the IC chip is arranged, to adhere the cover sheets to the IC chip through the adhesive.

The electrically conductive member may be a lead frame or a wiring tab. The electrically conductive member may be fixed onto the terminal surface area through at least one of soldering, welding, an electrically conductive adhesive, ACF connection and crimping. In this specification, a direct connect or mount means a connection or mounting without any element between members to be connected to each other (for example, welding, crimping or the like), and another connection or mounting with bump of solder or electrically conductive adhesive between the members.

The casing is preferably made of PET or polyvinyl chloride. The resin is preferably an epoxy resin. The electrically conductive member is preferably made of Nickel-base alloy, a steel plated with anti-corrosion metal, stainless steel or the like, and the antenna coil is preferably made of copper, copper-base alloy, aluminum, aluminum alloy, or the like.

### BRIEF DESCRIPTION OF THE DRAWINGS

FIG. 1 is a perspective view of a semiconductor module in accordance with a first embodiment;

FIG. 2 is a cross sectional view of the semiconductor module in accordance with the first embodiment;

FIG. 3 is a schematic view which explains a method of producing the semiconductor module in accordance with the first embodiment;

FIG. 4 is a schematic view which explains another method of producing the semiconductor module in accordance with the first embodiment;

FIG. 5 is a cross sectional view of a semiconductor module in accordance with a second embodiment;

FIG. 6 is a schematic view which explains a method of producing the semiconductor module in accordance with the second embodiment;

FIG. 7 is a perspective view of a semiconductor module in accordance with a third embodiment;

FIG. 8 is a cross sectional view of the semiconductor module in accordance with the third embodiment;

FIG. 9 is a schematic view which explains a method of producing the semiconductor module in accordance with the third embodiment;

FIG. 10 is a cross sectional view of a semiconductor module in accordance with a fourth embodiment;

FIG. 11 is a schematic view which explains a method of producing the semiconductor module in accordance with the fourth embodiment;

FIG. 12 is a table which shows a point pressure strength of the semiconductor module in accordance with the present invention in comparison with a point pressure strength of a bare IC chip in accordance with a conventional art;

FIG. 13 is a schematic view which shows a method of testing a point pressure strength;

FIG. 14 is a plan view which shows a non-contact IC card in accordance with a first embodiment in a partly cutting off manner;

FIG. 15 is a cross sectional view of the non-contact IC card in accordance with the first embodiment;

FIG. 16 is a cross sectional view which shows another example of the non-contact IC card in accordance with the first embodiment;

FIG. 17 is a cross sectional view of a wire constituting an antenna coil;

FIG. 18 is a schematic view which explains a method of connecting an antenna coil to a lead terminal;

FIG. 19 is a plan view which shows a non-contact IC card in accordance with a second embodiment in a partly cutting off manner;

FIG. 20 is a cross sectional view of the non-contact IC card in accordance with the second embodiment;

FIG. 21 is a cross sectional view which shows another example of the non-contact IC card in accordance with the second embodiment;

FIG. 22 is a cross sectional view of a non-contact IC card in accordance with a third embodiment;

FIG. 23 is a flow chart which shows a method of producing a semiconductor apparatus in accordance with a first embodiment;

FIG. 24 is a plan view which shows a part of a lead frame or a connecting tab;

FIG. 25 is a plan view of a lead frame or a connecting tab to which a bare IC chip is connected;

FIG. 26 is a cross sectional view of a non-woven fabric to which a circuit module is temporarily attached;

FIG. 27 is a schematic view which shows casing means for a flexible IC module;

FIG. 28 is a flow chart which shows a method of producing a semiconductor apparatus in accordance with a second embodiment;

FIG. 29 is a cross sectional view of a cover sheet to which a circuit module is temporarily attached; and

FIG. 30 is a schematic view which shows casing means for a circuit module.

### DETAILED DESCRIPTION OF PREFERRED EMBODIMENTS

First Embodiment of Semiconductor Module

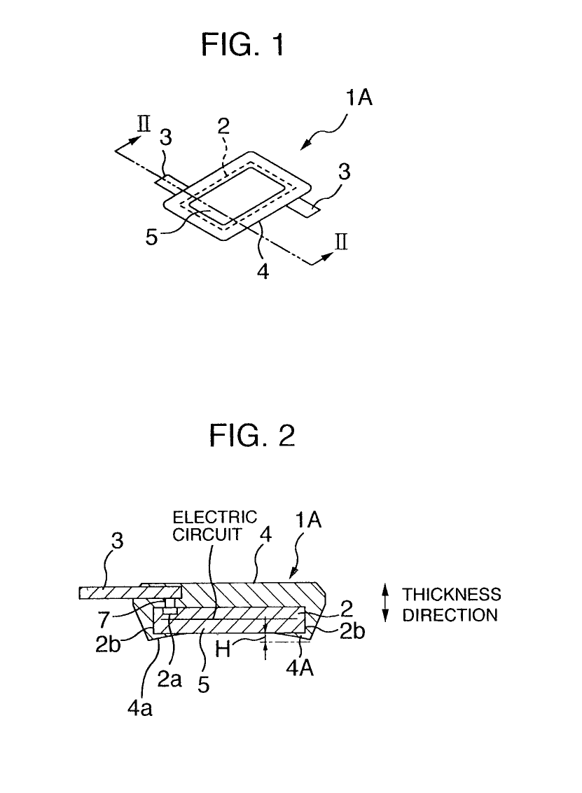

A first embodiment of a semiconductor module in accordance with the present invention will be described below with reference to FIGS. 1 to 4. FIG. 1 is a perspective view of a semiconductor module in accordance with the first embodiment, FIG. 2 is a sectional view along a line II-II in FIG. 1 and FIGS. 3 and 4 are views which explain a method of producing the semiconductor module in accordance with the first embodiment.

As shown in FIGS. 1 to 3, a semiconductor module 1A in accordance with the first embodiment is constituted by a bare IC chip 2, a lead terminal 3 as the claimed electrically conductive member directly connected to a pad portion 2a as the claimed electrically conductive terminal surface area of the IC chip 2 and a sealing resin 4 for sealing a periphery of the IC chip 2 with a part of the lead terminal 3, a thin resin film 4a is formed only at a peripheral portion including an edge portion 2b on a back surface side of the IC chip 2, and a center portion is formed as a chip exposing portion 5 having no sealing resin 4.

As the bare IC chip 2, an IC chip in which a gold bump or a nickel bump 7 is applied to the pad portion 2a corresponding to an input and output terminal is employed. As the bare IC chip 2, in the case of applying to a thin semiconductor apparatus, an IC chip obtained by applying an abrasion process to a silicon wafer by mechanical or chemical means or a combination thereof so as to be made thin to a desired thickness can be employed.

An end of the lead terminal 3 made of an electrically conductive material having a relatively high rigidity is directly connected to the pad portion 2a of the bare IC chip 2 via a bump 7 made of gold, nickel, solder or the like, as shown in FIG. 2. As the lead terminal 3, a lead terminal formed by a lead frame made of an electrically conductive metal material may be employed, or a lead terminal formed by a connecting tab structured such that an electric conducting pattern is provided on an insulative resin substrate may be employed, and a connection between the bump 7 and the lead terminal 3 can be performed by a thermal pressure connection, a solder connection, a welding, an electrically conductive paste connection, an anisotropic electrically conductive binding material or adhesive (ACF) connection, an ultrasonic welding or the like.

The sealing resin 4 is constituted by a high bridging thermosetting resin material excellent in mechanical and chemical characteristics such as an epoxy resin or the like, and is formed in the periphery of the IC chip 2 with the connecting portion of the lead terminal 3. A thin resin film 4a formed on the back surface side of the bare IC chip 2 is formed such that a film thickness is thickest at a portion corresponding to the edge portion 2b of the bare IC chip 2 as shown in FIG. 2 and becomes sequentially thin toward a center portion side of the bare IC chip 2. A maximum film thickness H of the resin film 4a can be optionally adjusted in accordance with a total thickness of the semiconductor apparatus which will apply this, and in the case of applying to a thin semiconductor apparatus, it is preferably set to a value equal to or more than 10 μm and equal to or less than the thickness of the IC chip 2. The resin layers formed on the surface side and the side surface side of the bare IC chips 2 can be made thicker than the thickness mentioned above, however, it is preferable that the total thickness of the semiconductor module 1A is set to be equal to or less than 0.5 mm in order to correspond to a thinning of the semiconductor apparatus.

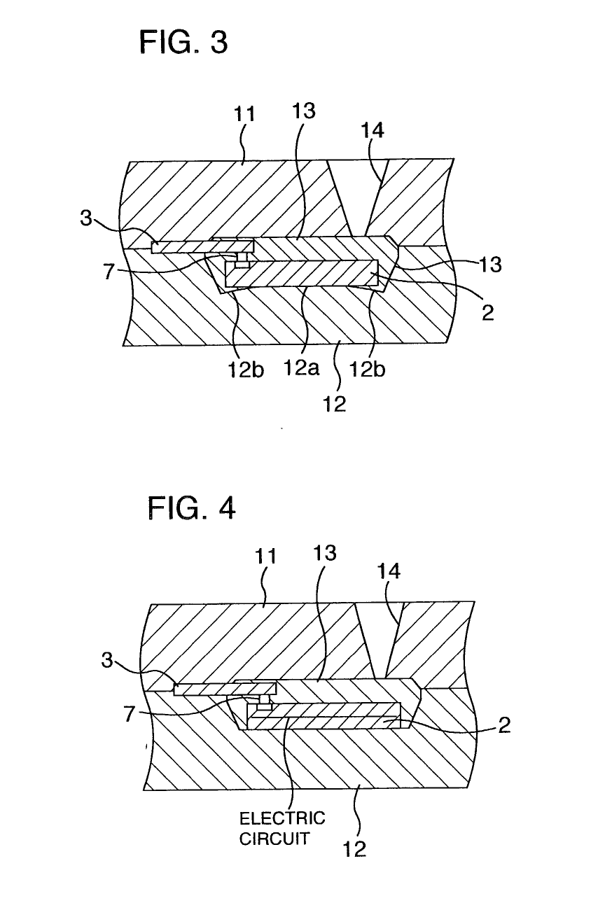

In this case, the resin sealing of the bare IC chip 2 in which the lead terminal 3 is connected to the pad portion 2a can be performed by pouring a resin into a metal mold cavity to which the bare IC chip 2 and the lead terminal 3 are received and fixed, as shown in FIGS. 3 and 4. FIG. 3 shows a case of forming the sealing resin 4 onto opposing surfaces of an upper mold 11 and a lower mold 12 by using a metal mold on which a cavity 13 having a shape corresponding to the sealing resin 4 to be formed is formed, and FIG. 4 shows a case of forming the sealing resin 4 onto the opposing surfaces of the upper mold 11 and the lower mold 12 by using a metal mold on which a cavity 13 having no portion corresponding to the resin film 4a to be formed is formed.

In the case of using the metal mold shown in FIG. 3, a center of a flat portion 12a formed in the lower mold 12 and a center of the bare IC chip 2 are aligned, a peripheral portion of the bare IC chip 2 is overhung over an inclined portion 12b formed in the lower mold 12, the flat portion 12a and the back surface of the bare IC chip 2 closely contact each other, a front end side of the lead terminal 3 protruding from the cavity 13 is gripped between the upper mold 11 and the lower mold 12, and the bare IC chip 2 is fixed within the cavity 13. In this state, when charging the resin into the cavity 13 from a gate portion 14, it is possible to obtain the sealing resin 4 formed in a desired shape having a wafer exposing portion 5 corresponding to the flat portion 12a of the cavity 13 and the resin film 4a corresponding to the inclined portion 12b.

In the case of using the metal mold shown in FIG. 4, the front end side of the lead terminal 3 protruding from the cavity 13 is gripped between the upper mold 11 and the lower mold 12 in a state of bringing the back surface of the bare IC chip 2 into contact with the cavity surface of the lower mold 12, whereby the bare IC chip 2 is fixed within the cavity 13. In this state, when charging the resin into the cavity 13 from the gate portion 14, the resin enters between the cavity surface of the lower mold 12 and the back surface of the bare IC chip 2 as a burr at a little amount, so that the wafer exposing portion 5 having no resin film is formed at the center portion on the back surface side of the bare IC chip 2, and the thin resin film 4a is formed in the peripheral portion on the back side of the bare IC chip 2.

Second Embodiment of Semiconductor Module

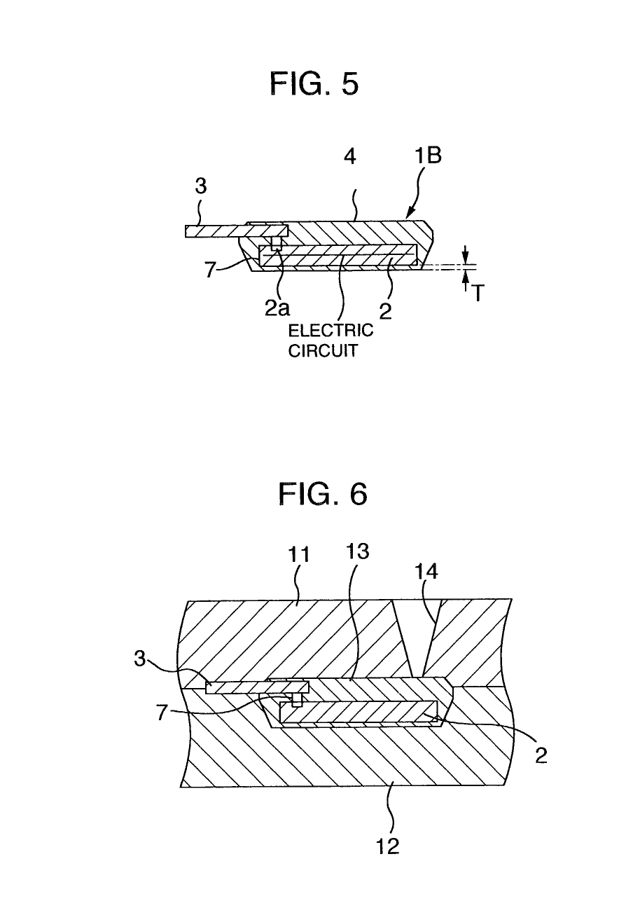

A second embodiment of the semiconductor module in accordance with the present invention will be described below with reference to FIGS. 5 and 6. FIG. 5 is a cross sectional view of the semiconductor module in accordance with the second embodiment, and FIG. 6 is a view explaining a method of producing the semiconductor module in accordance with the second embodiment.

As shown in FIGS. 5 and 6, a semiconductor module 1B in accordance with the second embodiment is structured such that a whole of an outer surface of a bare IC chip 2 with a connecting portion of the lead terminal 3 is covered by the sealing resin 4. A film thickness T of a resin layer formed on a back surface side of the bare IC chip 2 is adjusted to a thickness equal to or more than 10 μm and equal to or less than a thickness of the bare IC chip 2 in order to make it possible to apply to a thin type semiconductor apparatus. With respect to a structure of the other portions, since the structure is the same as that of the semiconductor module in accordance with the first embodiment, an explanation thereof will be omitted so as to avoid repetition.

The semiconductor module 1B in accordance with the present embodiment can be produced by using a metal mold shown in FIG. 6. As is apparent from FIG. 6, the metal mold of the present embodiment is formed such that a cavity 13 formed in opposing surfaces between an upper mold 11 and a lower mold 12 is formed is formed in a shape corresponding to the sealing resin 4 to be formed and a desired distance equal to or more than 10 μm and equal to or less than the thickness of the bare IC chip 2 is formed between the back surface of the bare IC chip 2 and the cavity surface of the lower mold 12 when gripping a front end side of the lead terminal 3 protruding from the cavity 13 between the upper mold 11 and the lower mold 12. The semiconductor module 1B in accordance with the present embodiment can be formed by gripping the front end side of the lead terminal 3 protruding from the cavity 13 between the-upper mold 11 and the lower mold 12 and charging the resin from the gate portion 14 into the cavity 13 in a state of adjusting the distance between the back surface of the bare IC chip 2 and the cavity surface of the lower mold 12 to a value equal to or more than 10 μm and equal to or less than the thickness of the bare IC chip 2.

Third Embodiment of Semiconductor Module

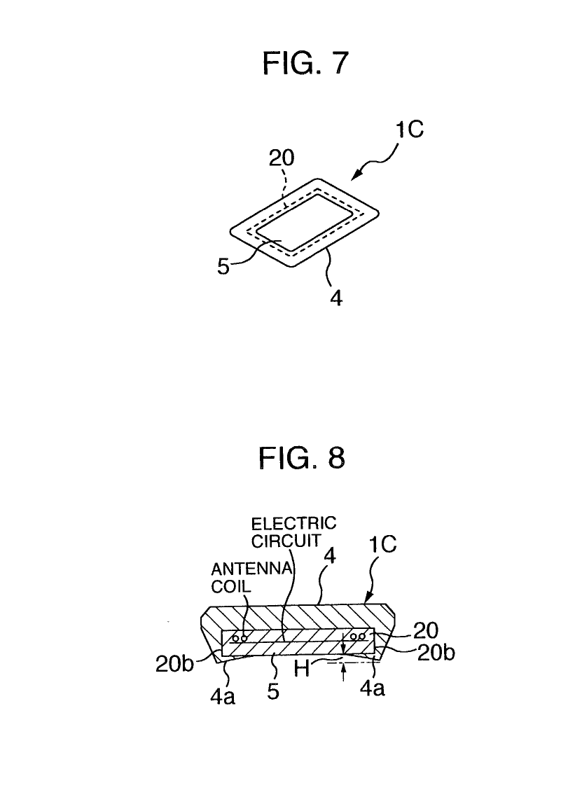

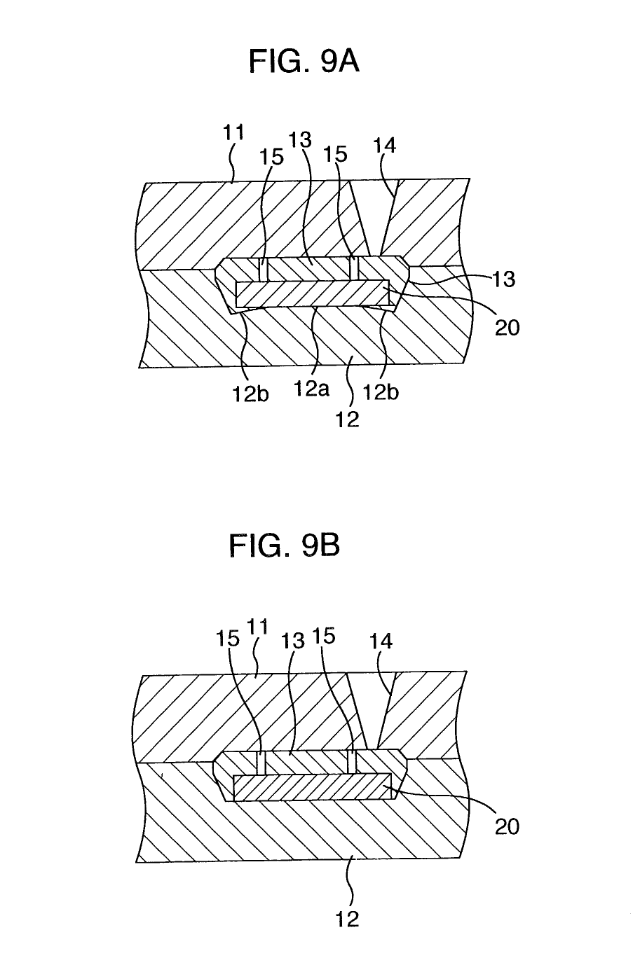

A third embodiment of the semiconductor module in accordance with the present invention will be described below with reference to FIGS. 7 to 9. FIG. 7 is a perspective view of a semiconductor module in accordance with the third embodiment, FIG. 8 is a cross sectional, and FIG. 9 is a view explaining a method of producing the semiconductor module in accordance with the third embodiment.

As shown in FIGS. 7 to 9, a semiconductor module 1C in accordance with the third embodiment is structured such as to employ an antenna coil installing type bare IC chip 20 having no pad portion and no lead terminal directly connected to the pad portion and seal an outer periphery of the antenna coil installing type IC chip 20 except a part of a back surface thereof by the sealing resin 4. On the back surface side of the IC chip 20, a thin resin film 4a is formed only at a peripheral portion including an edge portion 20b, and a center portion thereof forms a wafer-exposing portion 5 having no sealing resin 4. With respect to a structure of the other portions, since the structure is the same as that of the semiconductor module 1A in accordance with the first embodiment, an explanation thereof will be omitted so as to avoid repetition.

The semiconductor module 1C in accordance with the present embodiment can be produced by using a metal mold shown in FIGS. 9A and 9B. The metal mold shown in FIG. 9A is formed such that a cavity 13 formed in opposing surfaces between an upper mold 11 and a lower mold 12 is formed is formed in a shape corresponding to the sealing resin 4 to be formed, and the metal mold shown in FIG. 9B is formed such that the cavity 13 having no portion corresponding to the resin film 4a mentioned above is formed in the opposing surfaces between an upper mold 11 and a lower mold 12. Since both of the metal molds are different from the metal molds shown in FIG. 3 and 4 and have no gripping portion for the lead terminal on the opposing surface between the upper mold 11 and the lower mold 12, in order to fix the antenna coil installing type IC chip 20 to a desired position within the cavity 13, the structure is made such that a pin 15 provided in the upper mold 11 is protruded into the cavity 13.

In the case of using the metal mold shown in FIG. 9A, a flat portion 12a and the back surface of the bare IC chip 20 are closely contacted with each other by the pin 15 protruded into the cavity 13 in a state of aligning a center of the flat portion 12a formed in the lower mold 12 with a center of the bare IC chip 20 so as to overhang a peripheral portion of the bare IC chip 20 over an inclined portion 12b formed in the lower mold 12. In this state, when charging the resin into the cavity 13 from the gate portion 14, it is possible to obtain the sealing resin 4 formed in a desired shape having a wafer exposing portion 5 corresponding to the flat portion 12a of the cavity 13 and the resin film 4a corresponding to the inclined portion 12b. On the contrary, in the case of using the metal mold shown in FIG. 9B, the back surface of the bare IC chip 20 is slightly brought into contact with the cavity surface of the lower mold 12 by the pin 15 protruded into the cavity 13. In this state, when charging the resin into the cavity 13 from the gate portion 14, the resin enters between the cavity surface of the lower mold 12 and the back surface of the bare IC chip 20 as a burr at a little amount, so that the wafer exposing portion 5 having no resin film is formed at the center portion on the back surface side of the bare IC chip 20, and the thin resin film 4a is formed in the peripheral portion on the back side of the bare IC chip 20.

Fourth Embodiment of Semiconductor Module

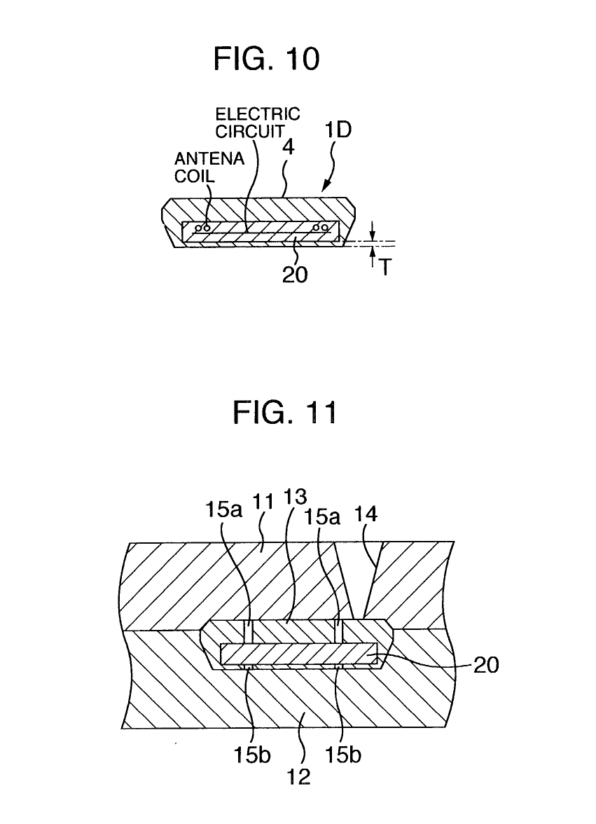

A fourth embodiment of the semiconductor module in accordance with the present invention will be described below with reference to FIGS. 10 and 11. FIG. 10 is a cross sectional view of the semiconductor module in accordance with the fourth embodiment, and FIG. 11 is a view explaining a method of producing the semiconductor module in accordance with the fourth embodiment.

As shown in FIGS. 10 and 11, a semiconductor module 1D in accordance with the fourth embodiment is structured such that a whole of an outer surface of an antenna coil installing type bare IC chip 20 is structured such as to be covered by the sealing resin 4. A film thickness T of a resin layer formed on a back surface side of the bare IC chip 20 is adjusted to a thickness equal to or more than 10 μm and equal to or less than a thickness of the bare IC chip 20 in order to make it possible to apply to a thin type semiconductor apparatus. With respect to a structure of the other portions, since the structure is the same as that of the semiconductor module in accordance with the third embodiment, an explanation thereof will be omitted so as to avoid repetition.

The semiconductor module 1D in accordance with the present embodiment can be produced by using a metal mold shown in FIG. 11. The metal mold shown in FIG. 11 is structured such that the cavity 13 formed in opposing surfaces between the upper mold 11 and the lower mold 12 is formed is formed in a shape corresponding to the sealing resin 4 to be formed and in order to fix the antenna coil installing type IC chip 20 to a desired position within the cavity 13, pins 15a and 15b provided in the upper mold 11 and the lower mold 12 are protruded into the cavity 13. A protruding amount of the pin 15b provided in the lower mold 12 is adjusted to a thickness of the resin layer to be formed on the back surface of the antenna coil installing type IC chip 20. The semiconductor module 1D in accordance with the present embodiment can be formed by placing the antenna coil installing type bare IC chip 20 on the pin 15b provided in the lower mold 12 and charging the resin from the gate portion 14 into the cavity 13 in a state of pressing the upper surface of the bare IC chip 20 by the pin 15a provided in the upper mold 11.

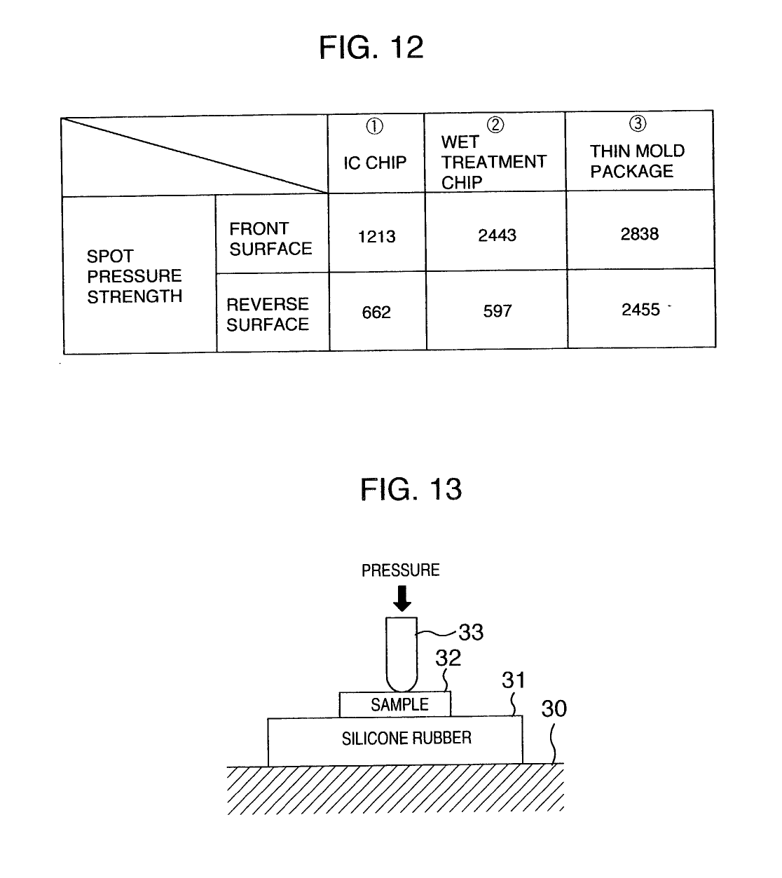

FIG. 12 shows a point or spot pressure strength of the semiconductor modules 1A, 1B, 1C and 1D in accordance with the present invention in comparison with a point or spot pressure strength of a bare IC chip to which a wet process is not applied at a final stage for dicing in accordance with a conventional embodiment and a point or spot pressure strength of a bare IC chip to which a wet process is applied at a final stage for dicing. A test for measuring the point pressure strength is performed with respect to both of a pad forming surface side (a front surface side) and a back surface side of a test piece 32 in accordance with a method of placing the test piece 32 on an upper surface of a silicone rubber 31 placed on a surface plate 30, vertically pressing a pressing jig 33 having a front end formed in a spherical shape to a center portion of the test piece 32 and applying a pressure until the test piece 32 is broken, as shown in FIG. 13. Values in FIG. 12 respectively express average values of data obtained with respect to twenty test pieces.

As is apparent from FIG. 12, in the normal bare IC chip to which the wet process is not applied at the final stage for dicing, the point pressure strength in the front surface side is 1213 gram and the point pressure strength in the back surface side is 662 gram. The point pressure strength on the back surface side is significantly lower than that in the front surface side because a chipping and a crack are easily generated in the back surface side of the IC chip at the producing stage and a stress is concentrated into these defects. On the contrary, in the bare IC chip to which the wet process is applied at the final stage for dicing, the point pressure strength in the front surface side is 2443 gram and the point pressure strength in the back surface side is 597 gram. Accordingly, it is understood that a great effect can be obtained for improving the point pressure strength in the front surface side. However, with respect to the back surface side, the point pressure strength is rather lower than the normal bare IC chip to which the wet process is not applied at the final stage for dicing (the reason therefor is not clear), and it is understood that the effect of the wet process is hardly obtained.

On the contrary, in the semiconductor module in accordance with the present invention, the point pressure strength in the front surface side and the point pressure strength in the back surface side are respectively increased to 2838 gram and 2455 gram, and it is understood that a great effect can be obtained for improving the point pressure strength with respect to both of the front surface side and the back surface side. In particular, since the point pressure strength in the back surface side is increased to a value corresponding to the point pressure strength in the front surface side of the bare IC chip to which the wet process is applied at the final stage for dicing, in the case of being mounted to a semiconductor apparatus in which a bending stress is repeatedly operated to the front surface side and the back surface side, it is possible to improve a durability thereof.

First Embodiment of Semiconductor Apparatus

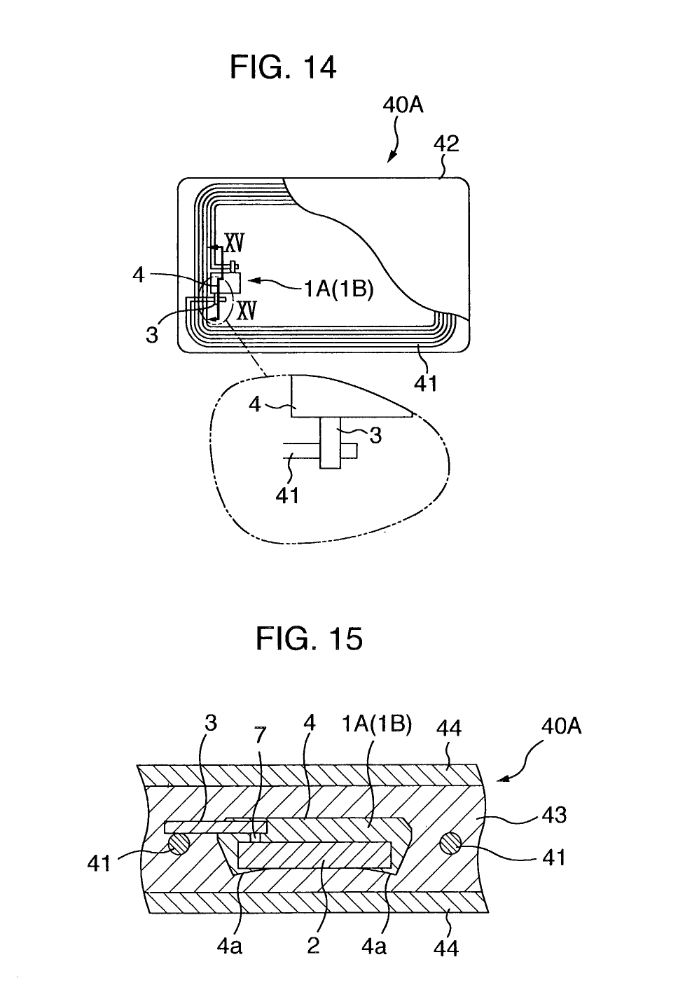

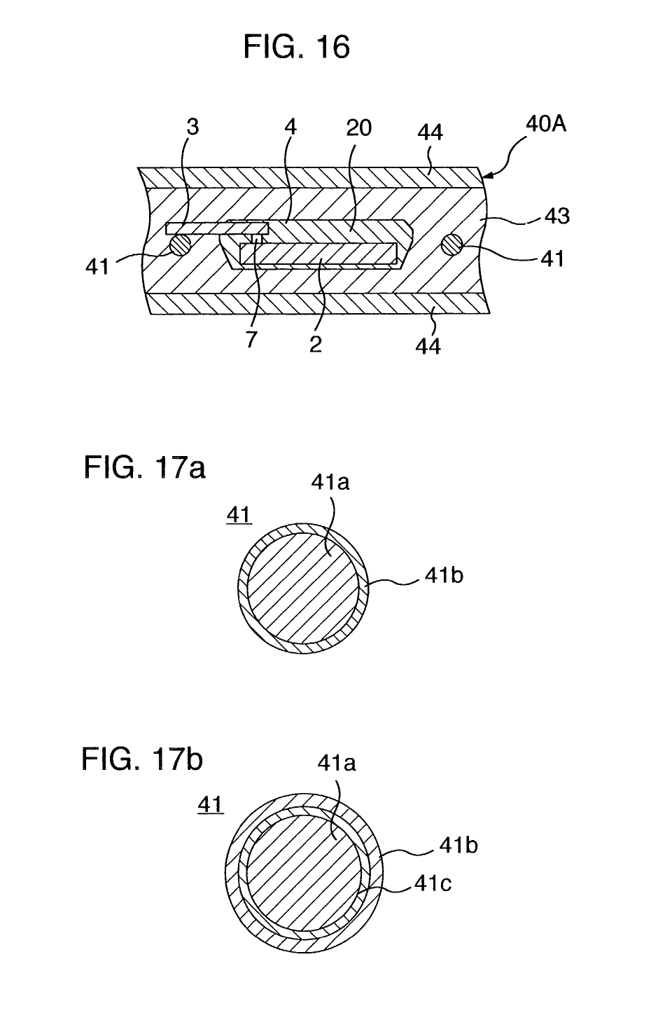

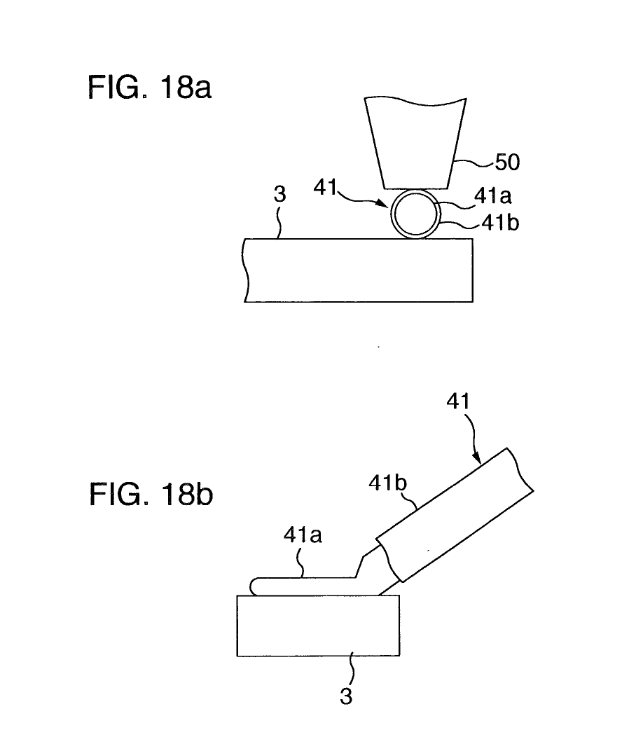

Hereinafter, a semiconductor apparatus in accordance with a first embodiment will be described with reference to FIGS. 14 to 18. The semiconductor apparatus in accordance with the first embodiment is characterized by mounting the semiconductor modules 1A or 1B shown in FIGS. 2 and 5. FIG. 14 is a plan view which shows a non-contact IC card in accordance with the first embodiment in a partly cutting off manner, FIG. 15 is a cross sectional view of a non-contact IC card to which the semiconductor module 1A shown in FIG. 2 is mounted, FIG. 16 is a cross sectional view of a non-contact IC card to which the semiconductor module 1B shown in FIG. 5 is mounted, FIG. 17 is a cross sectional view of a wire constituting an antenna coil, and FIG. 18 is a view explaining a method of connecting the antenna coil to a lead terminal.

As is apparent from FIGS. 14 to 16, a non-contact IC card 40A in accordance with the present embodiment is constituted by the semiconductor module 1A or 1B, an antenna coil 41 electrically connected to the semiconductor module 1A or 1B and a base body 42 installing each of the mounted parts.

The antenna coil 41 is connected to a front end portion of the lead terminal 3 protruding from the sealing resin 4 of the semiconductor module 1A or 1B in accordance with a connecting method, for example, a wedge bonding, a solder bonding, a welding, an electrically conductive paste bonding or the like. As a wire constituting the antenna coil 41, it is possible to employ a wire structured such that an insulating layer 41b such as a resin or the like is coated around a core wire 41a made of or including a good electrically conductive metal material such as a copper, an aluminum or the like as shown in FIG. 17A, or a wire structured such that a bonding metal layer 41c such as a gold, a solder or the like is coated around the core wire 41a and the insulating layer 41b is coated around the bonding metal layer 41c as shown in FIG. 17B. A diameter of the wire is 20 am to 100 μm, and the antenna coil 41 is formed by turning the wire at some to some tens times in correspondence to a characteristic of the IC chip 2.

In the case of connecting the antenna coil 41 to the lead terminal 3 by the wedge bonding method, it is possible to employ a structure having no bonding metal layer 41c as the antenna coil 41, however, in order to more easily and securely perform the bonding, it is particularly preferable to employ a structure in which the metal is coated around the core wire 41a. The wedge bonding between the antenna coil 41 and the lead terminal 3 is performed by overlapping the antenna coil 41 on the lead terminal 3, pressing a bonding tool 50 from the antenna coil 41 side, applying an ultrasonic, sublimating the insulating layer 41b by the energy and melting the metal, as shown in FIG. 18A. The antenna coil 41 connected by the wedge bonding is structured such that the insulating layer 41b near the pressurizing portion is broken away and the core wire 41a crushed into a flat shape is crimped to the lead terminal 3, as shown in FIG. 18B.

A base body 42 is constituted by a binding material layer 43 which may include non-woven fabric and a cover sheet 44 as the claimed casing bonded to a surface of the binding material layer 43, as shown in FIGS. 15 and 16.

As a binding material constituting the binding material layer 43, it is possible to employ a known optional binding material as far as it has a desired strength after hardening, however, it is particularly preferable to employ a thermoplastic elastomer or a mixed body between a thermoplastic elastomer and a resin since it can be bonded by a roll press or a hydrostatic press and a warp is hardly generated after hardening.

The cover sheet 44 can be constituted by an optional insulative resin sheet, however, it is particularly preferable to employ a polyethylene terephthalate (PET), a polyvinyl chloride (PVC) or the like since it has a high strength and is excellent in a bonding characteristic and a printing characteristic.

Since the non-contact IC card 40A in accordance with the present embodiment is structured such that the semiconductor module 1A or 1B in which the IC chip 2 is sealed by the resin is mounted, the IC chip is hard to be broken even when the repeating bending stress is applied and the durability of the non-contact IC cart 40A is excellent in durability. Further, since the semiconductor module 1A or 1B excellent in the point pressure strength and an impact resisting strength is mounted, it is possible to reduce a total thickness of the base body 42, and it is possible to further thin this kind of semiconductor apparatus.

Second Embodiment of Semiconductor Apparatus

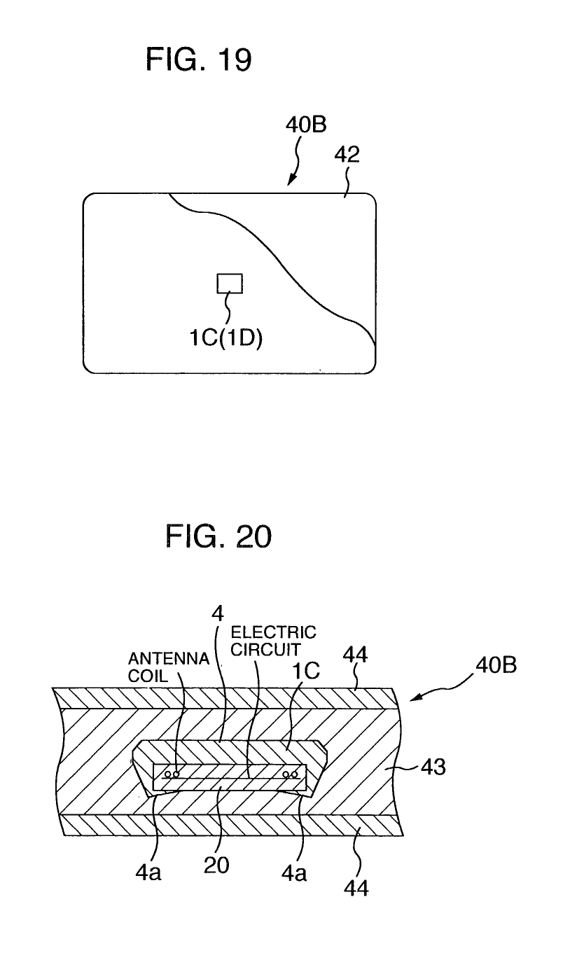

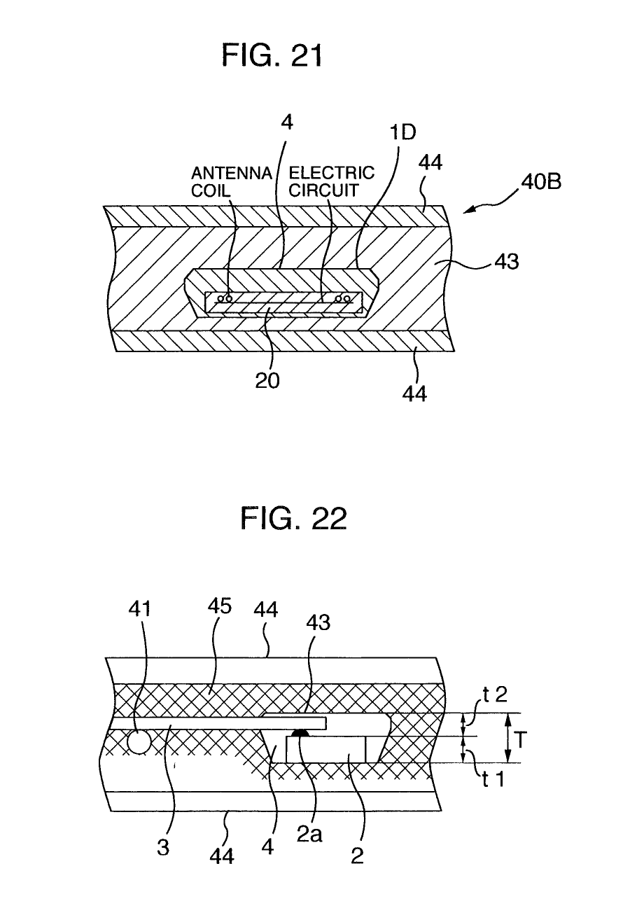

Next, a semiconductor apparatus in accordance with a second embodiment will be described below with reference to FIGS. 19 to 21. The semiconductor apparatus in accordance with the second embodiment is characterized by mounting the semiconductor modules 1C or 1D shown in FIGS. 8 and 10. FIG. 19 is a plan view which shows a non-contact IC card in accordance with the second embodiment in a partly cutting off manner, FIG. 20 is a cross sectional view of a non-contact IC card to which the semiconductor module 1C shown in FIG. 8 is mounted, and FIG. 21 is a cross sectional view of a non-contact IC card to which the semiconductor module 1D shown in FIG. 10 is mounted.

As is apparent from these drawings, a non-contact IC card 40B in accordance with the present embodiment is structured such as to simply case the semiconductor module 1C or 1D in which the antenna coil installing IC chip 20 is sealed by the resin by the base body 42. Since the structure of the base body 42 is the same as that of the non-contact IC card 40A in accordance with the first embodiment, the same reference numerals are attached to the corresponding elements and an explanation thereof will be omitted. The binding material or adhesive layer 43 may include non-woven fabric or may be a non-woven fabric including binding material or adhesive layer 43, that is, the binding material or adhesive layer 43 may be non-woven fabric 45 impregnated with the binding material or adhesive as described below.

Since the non-contact IC card 40B in accordance with the present embodiment is structured such that the semiconductor module 1C or 1D in which the IC chip 20 is sealed by the resin is mounted, in addition to the same effects as those of the non-contact IC card 40A in accordance with the first embodiment, it is possible to further thin this kind of semiconductor apparatus and reduce cost thereof since the lead terminal 3 and the antenna coil 41 are not required by employing the antenna coil installing IC chip 20.

Third Embodiment of Semiconductor Apparatus

Next, a semiconductor apparatus in accordance with a third embodiment will be describe below with reference to FIG. 22. The semiconductor apparatus in accordance with the third embodiment is characterized by interposing a non-woven fabric in a binding material layer or adhesive 43 or impregnating the non-woven fabric with the adhesive to constitute the base body 42. FIG. 22 is a cross sectional view of a non-contact IC card in accordance with the third embodiment.

In this drawing, reference numeral 45 denotes a non-woven fabric, and the non-woven fabric 45 is impregnated with a binding material or adhesive to constitute the binding material or adhesive layer 43 as the second embodiment of semiconductor apparatus. It is possible to employ a known optional non-woven fabric as the non-woven fabric 45 to the non-contact IC card 40C in accordance with the third embodiment. Since the structure of the other elements is the same as that of the non-contact IC card 40A in accordance with the first embodiment, an explanation thereof will be omitted so as to avoid repetition.

Since the non-contact IC card 40C in accordance with the present embodiment is structured such that the semiconductor module 1C or 1D in which the IC chip 2 is sealed by the resin is mounted, in addition to the same effects as those of the non-contact IC card 40A in accordance with the first embodiment, a strength and a rigidity of the base body 42 are increased and it is possible to further thin this kind of semiconductor apparatus and increase a reliability thereof since the non-woven fabric 45 is interposed in or impregnated with the binding material layer 43.

Here, FIG. 22 only shows the case that the semiconductor module 1A in accordance with the first embodiment is mounted, however, the same structure can be realized in the case that the semiconductor module 1B in accordance with the second embodiment is mounted, in the case that the semiconductor module 1C in accordance with the third embodiment is mounted, and in the case that the semiconductor module 1D in accordance with the fourth embodiment is mounted.

First Embodiment of Method of Producing Semiconductor Apparatus

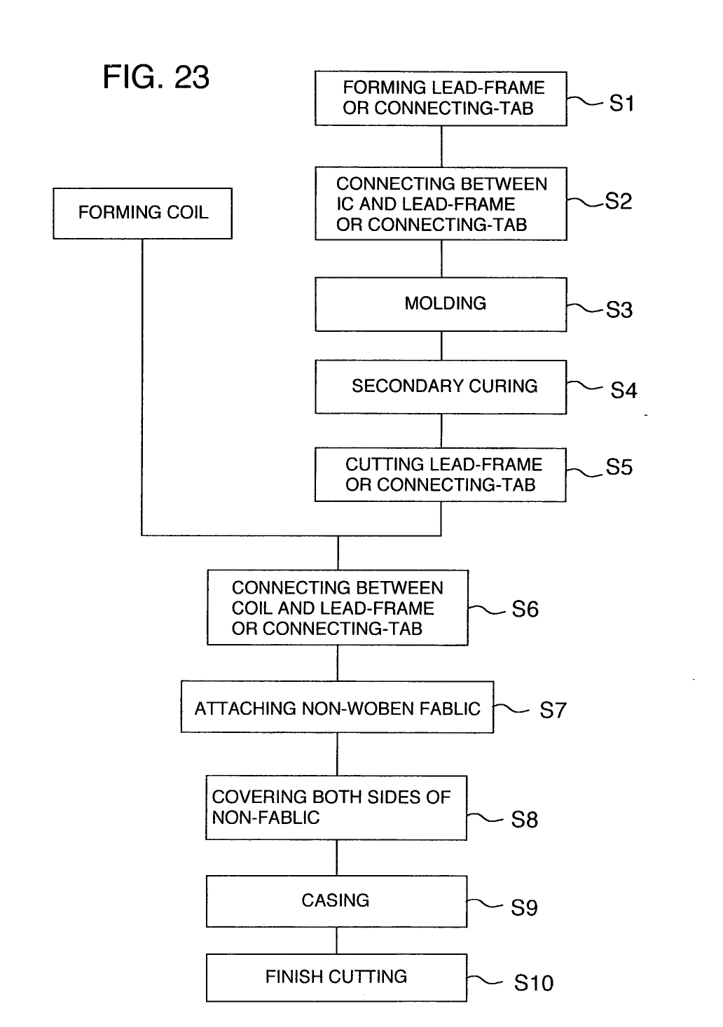

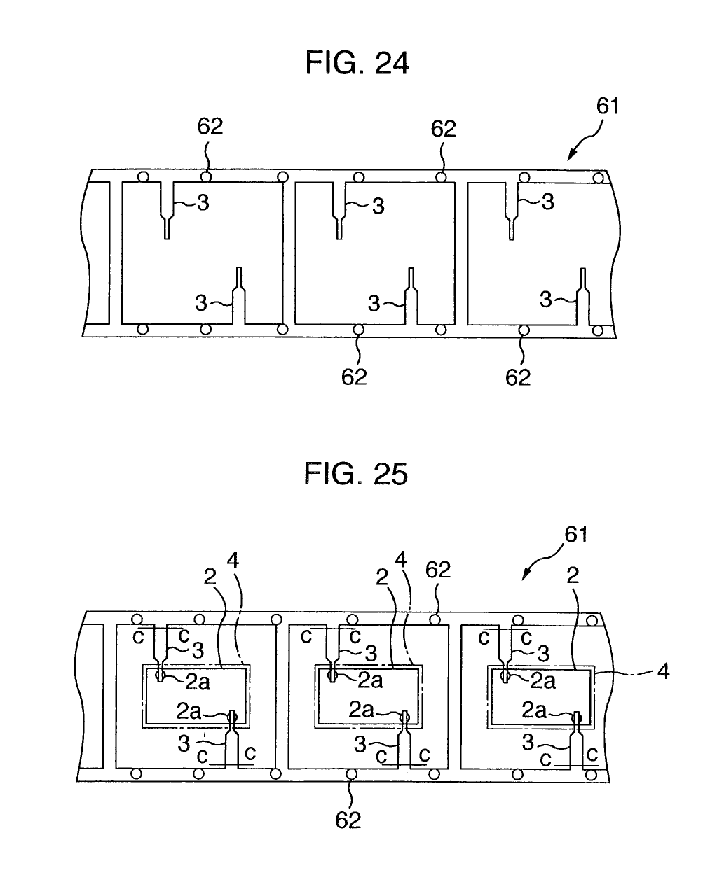

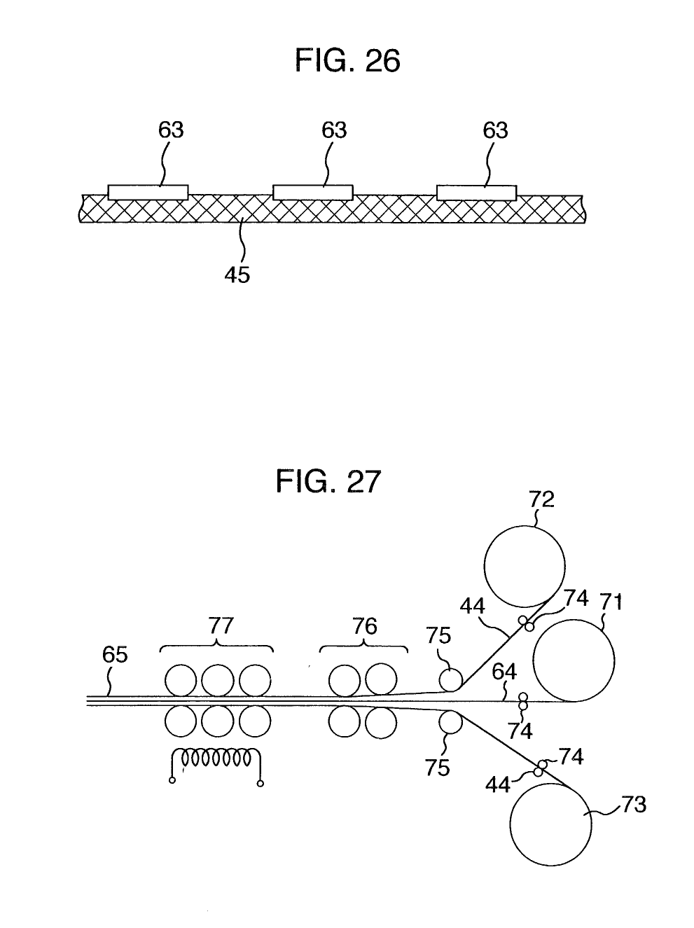

Hereinafter, a description will be given of a method of producing the non-contact IC card 40C in accordance with the third embodiment with reference to FIGS. 23 to 29. FIG. 22 is a flow chart showing a first embodiment of the producing method, FIG. 24 is a plan view showing a part of the lead frame or the connecting tab, FIG. 25 is a plan view of the lead frame or the connecting tab to which the bare IC chip is connected, FIG. 26 is a cross sectional view of the non-woven fabric to which a circuit module is temporarily mounted, and FIG. 27 is a schematic view showing casing means for a flexible IC module.

At first, as shown in FIG. 24, there is prepared a ribbon-like lead frame or connecting tab 61 in which a multiplicity of lead terminals 3 as the claimed electrically conductive member) are formed at a fixed interval (a step S1 in FIG. 23). In this case, reference numeral 62 in FIG. 24 denotes a through hole used for transferring the lead frame or the connecting tab 61 and the through holes are pierced out of the portion forming the lead terminal 6 at a fixed pitch.

Next, as shown in FIG. 25, the bare IC chip 2 is connected to each of the lead terminals 3 formed in the lead frame or the connecting tab 61 (a step S2 in FIG. 23). A connection between the lead terminal 3 and the bare IC chip 2 is performed by previously placing the gold bump 7 on the pad portion 2a of the bare IC chip 2 and soldering, welding, connecting by the conductive paste or ultrasonic welding the gold bump 7 and the lead terminal 3.

The lead frame or the connecting tab 61 to which the bare IC chip 2 is connected is successively fed into the mold metal mold shown in FIG. 3 from the front end portion by using the through hole 62 mentioned above and the periphery of the bare IC chip 2 including the connecting portion of the lead terminal 3 is molded, by the resin (a step S3 in FIG. 23).

The bare IC chip 2 and the lead frame or the connecting tab 61 after being molded by the resin are placed within a cure furnace and a secondary cure is performed (a step S4 in FIG. 23).

The lead terminal 3 is cut along a line C-C in FIG. 25, and the semiconductor module 1A structured such that the bare IC chip 2 and the lead terminal 3 are integrally molded by the resin is taken out (a step S5 in FIG. 23).

The independently produced antenna coil 41 is connected to the lead terminal 3 of the semiconductor module 1A so as to obtain a circuit module 63 structured such that the semiconductor module 1A and the antenna coil 41 are integrally molded (a step S6 in FIG. 23). As a method of connecting the antenna coil 41 and the lead terminal 3, it is possible to select any one of the solder connection, the welding, the electrically conductive paste or adhesive connection and the crimping connection.

The circuit module 63 obtained in this manner is temporarily attached to one surface of the non-woven fabric 45 having a compressibility and a self-crimping characteristic one by one as shown in FIG. 26 (a step S7 in FIG. 23). Here, the compressibility in the non-woven fabric 45 means a nature capable of installing all or a part of the circuit module 63 within the non-woven fabric 45 when pressing the circuit module 63 to the non-woven fabric 45 under heating, and the self-crimping characteristic means a nature capable of bonding fibers constituting the non-woven fabric 45 to each other and bonding the other member, for example, the circuit module 63 or the other non-woven fabric to the non-woven fabric 45 so as to keep a fixed shape when compressing under heating. The temporary attachment of the circuit module 63 to the non-woven fabric 45 is performed by pressing the circuit module 2 to one surface of the non-woven fabric 45 formed in a tape shape or a ribbon shape and arranging it at a fixed pitch.

The same kind of non-woven fabric 45 or a different kind of non-woven fabric 45 is overlapped on the circuit module mounting surface of the non-woven fabric 45 to which the circuit module 63 is temporarily attached and these two non-woven fabrics 45 are crimped under heating (a step S8 in FIG. 23). Accordingly, there is obtained a flexible IC module 64 in which a multiplicity of circuit modules 63 are gripped between the tape-like or ribbon-like non-woven fabrics 45 at a fixed pitch.

Next, the cover sheets 44 as the claimed casing are stuck onto both of the front and back surfaces of the flexible IC module 64 produced in the manner mentioned above via the binding material or layer or adhesive 43 so as to case the circuit module 63 (a step S9 in FIG. 23). The casing of the circuit module 63 is performed by preparing the flexible IC module 64 wound like a roll and the cover sheet 44 formed in a tape shape or a ribbon shape, wound like a roll and having the binding material layer 43 on one surface and sticking the cover sheet 44 drawn out from the rollers 72 and 73 to both of the front and back surfaces of the flexible IC module 64 drawn out from the roller 71 via the binding material layer 43, as shown in FIG. 27. In FIG. 27, reference numeral 74 denotes a drawing roller, reference numeral 75 denotes a transfer roller, reference numeral 76 denotes a sticking roller for temporarily attaching the flexible IC module 64 to the cover sheet 44, and reference numeral 77 denotes a thermal crimping roller for thermally crimping the temporarily attached body between the flexible IC module 64 and the cover sheet 44 so as to produce a card pattern 65 having a predetermined thickness. The binding material or adhesive layer 43 provided on one surface of the cover sheet 44 is melted in the process of passing through the thermal crimping roller 77, impregnating into the non-woven fabric 45, and integrally connecting the flexible IC module 64 to two cover sheets 44.

Here, in the embodiment shown in FIG. 27, the card pattern 65 is produced by using the thermal crimping roller 77, however, in place of this structure, it is possible to produce the card pattern 65 by using a static pressure press apparatus.

Finally, the card pattern 65 is cut so as to obtain the non-contact IC card 40C having a predetermined shape and size (a step S10 in FIG. 23).

In accordance with the producing method of the present embodiment, since it is possible to form all of the lead frame or the connecting tab 61, the flexible IC module 64 and the cover sheet 44 in a tape shape or a ribbon shape, and it is possible to automatically and continuously perform a process and a treatment in each of the steps, it is possible to increase a productivity of the desired non-contact IC card 40C.

Second Embodiment of Method of Producing Semiconductor Apparatus

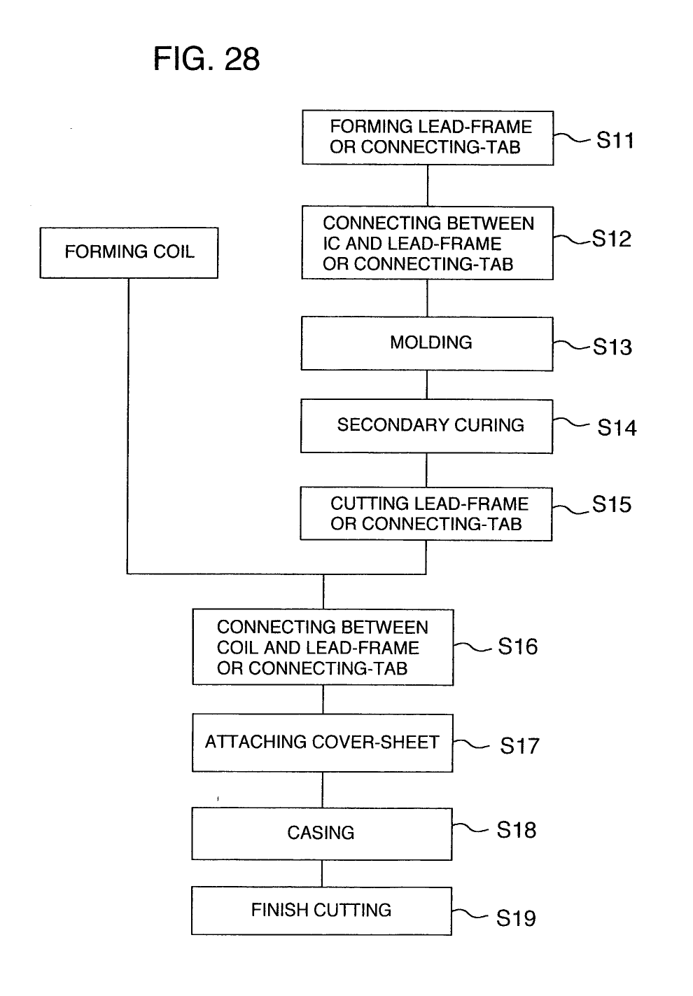

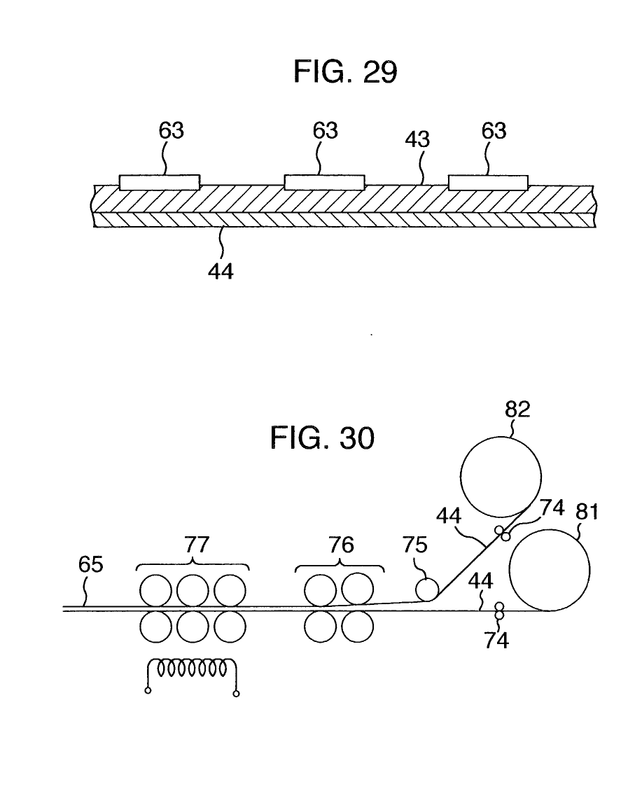

Hereinafter, a method of producing the non-contact IC card 40A in accordance with the first embodiment will be described with reference to FIGS. 28 to 30. FIG. 28 is a flow chart showing a procedure of a method of producing a semiconductor apparatus in accordance with a second embodiment, FIG. 29 is a cross sectional view of the cover sheet to which the circuit module is temporarily attached, and FIG. 30 is a schematic view showing the casing means of the circuit module.

As is apparent from FIG. 28, steps from a step S11 of producing the lead frame or the connecting tab to a step S16 of connecting the coil are respectively the same as the steps S1 to S6 in the method of producing the semiconductor apparatus in accordance with the first embodiment shown in FIG. 23. Further, since processes in the respective steps are the same as those in the case of the first embodiment, an explanation thereof will be omitted so as to avoid repetition.

The circuit modules 63 produced in the process to the step S6 are temporarily attached to the binding material layer forming surface of the cover sheet 44 as the claimed casing having one surface on which the binding material or adhesive layer 43 is formed, one by one as shown in FIG. 29 (a step S17 in FIG. 28). The temporary attachment of the circuit module 63 with respect to the binding material layer 43 is performed by pressing the circuit module 63 onto the binding material layer forming surface of the cover sheet 44 formed in a tape shape or a ribbon shape under heating and arranging at a fixed pitch.

Next, the cover sheet 44 as the claimed casing of the same kind as or of the different kind from the cover sheet 44 is bonded onto the circuit module mounting surface of the cover sheet 44 on which the circuit module 63 is temporarily attached, thereby casing the circuit module 63 (a step S18 in FIG. 28). The casing of the circuit module 63 is performed by previously winding both of the cover sheet 44 to which the circuit module 63 is temporarily attached and the cover sheet 44 having no circuit module 63 in a roll shape, and bonding both of the cover sheets 44 drawn out from the respective rollers 81 and 82 in a state of setting the binding material layer 43 inside, as shown in FIG. 30. In FIG. 30, reference numeral 74 denotes a drawing roller, reference numeral 75 denotes a transfer roller, reference numeral 76 denotes a sticking roller for temporarily attaching the flexible IC module 64 to the cover sheet 44, and reference numeral 77 denotes a thermal crimping roller for thermally crimping the temporarily attached body between the flexible IC module 64 and the cover sheet 44 so as to produce a card pattern 65 having a predetermined thickness. The binding material layer 43 provided on one surface of each of the cover sheets 44 is melted in the process of passing through the thermally crimping roller 77, installing the circuit module 63 within the binding material layer 43, and integrally connecting two cover sheets 44 to each other. Accordingly, the card pattern 65 is produced.

In this case, in the embodiment shown in FIG. 30, the card pattern 65 is produced by using the thermal crimping roller 77, however, it is possible to produce the card pattern 65 by using the static pressure press apparatus in place of the structure mentioned above.

Finally, the card pattern 65 is cut so as to obtain the non-contact IC card 1A having a predetermined shape and size (a step S19 in FIG. 28).

In accordance with the producing method of the present embodiment, in addition to the same effects as those of the first producing method, since the non-woven fabric is not used, it is possible to further increase a productivity of the non-contact IC card.

Here, in the step S17 shown in FIG. 28, if the antenna coil installing type bare IC chips 20 shown in FIGS. 8 and 10 are temporarily attached to the binding material layer forming surface of the cover sheet 44 having one surface on which the binding material layer 43 is formed one by one, it is possible to produce the semiconductor apparatus 40B in accordance with the second embodiment.

Further, in each of the embodiments mentioned above, the non-contact IC card and the producing method thereof are exemplified, however, it is possible to produce semiconductor apparatuses other than the card type, for example, a tag type or a coin type semiconductor apparatus by the same method.

What is claimed is:

1. A semiconductor module comprising,
an IC chip including an electric circuit and an electrically conductive terminal surface area connected electrically to the electric circuit,
an electrically conductive member fixed onto the terminal surface area with an electrical conductivity between the electrically conductive member and the terminal surface area, and
a resin adhering to a part of the electrically conductive member and to a part of the IC chip.

2. A semiconductor module according to claim 1, wherein the IC chip includes first and second surfaces opposite to each other in a thickness direction of the IC chip, the first surface includes the terminal surface area, the part of the electrically conductive member extends along a part of the first surface, and the resin is prevented from adhering to at least a part of the second surface.

3. A semiconductor module according to claim 1, wherein the IC chip includes first and second surfaces opposite to each other in a thickness direction of the IC chip, the first surface includes the terminal surface area, the part of the electrically conductive member extends along a part of the first surface, the second surface includes a peripheral area, and the resin adheres to at least a part of the peripheral area.

4. A semiconductor module according to claim 3, wherein the IC chip includes a third surface extending between the first and second surfaces, and the resin adheres to at least a part of the third surface to extend monolithically between the part of the electrically conductive member and the at least a part of the peripheral area.

5. A semiconductor module according to claim 1, wherein the IC chip includes first and second surfaces opposite to each other in a thickness direction of the IC chip, the first surface includes the terminal surface area, the part of the electrically conductive member extends along a part of the first surface, the second surface includes a peripheral area and a central area surrounded by the peripheral area, and the resin adheres to at least a part of the peripheral area and is prevented from adhering to the central area.

6. A semiconductor module according to claim 1, further comprising an antenna member fixed onto the electrically conductive member with an electrical conductivity between the antenna member and the electrically conductive member.

7. A semiconductor module according to claim 6, wherein a modulus of longitudinal elasticity of the antenna member is smaller than a modulus of longitudinal elasticity of the electrically conductive member.

8. A semiconductor module according to claim 6, wherein the electrically conductive member includes first and second sides opposite to each other in a thickness direction of the IC chip, the second side faces to the IC chip, and the antenna member is fixed onto the second side.

9. A semiconductor module according to claim 6, wherein the resin is prevented from adhering to the electrically conductive member monolithically from the terminal surface area to the antenna member.

10. A semiconductor module according to claim 6, wherein the electrically conductive member juts out with respect to the antenna member in both directions opposite to each other and perpendicular to a longitudinal direction of the antenna member.

11. A semiconductor module according to claim 6, wherein the antenna member juts out with respect to the electrically conductive member in both directions opposite to each other and perpendicular to a longitudinal direction of the electrically conductive member.

12. A semiconductor module according to claim 1, further comprising a casing receiving therein the IC chip, the electrically conductive member and the resin.

13. A semiconductor module according to claim 12, wherein a modulus of longitudinal elasticity of the casing is smaller than a modulus of longitudinal elasticity of the resin.

14. A semiconductor module according to claim 6, wherein the electrically conductive member extends substantially straight between the antenna member and the terminal surface area.

15. A semiconductor module according to claim 1, wherein the IC chip includes first and second surfaces opposite to each other in a thickness direction of the IC chip, the first surface includes the terminal surface area, the part of the electrically conductive member extends along a part of the first surface, and the resin adheres to the whole of the second surface.

16. A semiconductor module according to claim 12, wherein the IC chip includes first and second surfaces opposite to each other in a thickness direction of the IC chip, the first surface includes the terminal surface area, the part of the electrically conductive member extends along a part of the first surface, and the casing is fixed onto at least a part of the second surface while the resin is prevented from existing between the casing and the at least a part of the second surface.

17. A semiconductor module comprising,
an IC chip including an electric circuit and an antenna coil, connected electrically to each other, and
a resin adhering to at least a part of the IC chip,
wherein the IC chip includes first and second surfaces opposite to each other in a thickness direction of the IC chip, the antenna coil is juxtaposed with the electric circuit in the thickness direction and extends substantially along an imaginary plane parallel to the first and second surfaces, a distance between the antenna coil and the first surface is smaller than a distance between the antenna coil and the second surface in the thickness direction.

18. A semiconductor module according to claim 17, wherein the resin is prevented from adhering to at least a part of the second surface.

19. A semiconductor module according to claim 17, wherein the second surface includes a peripheral area, and the resin adheres to at least a part of the peripheral area.

20. A semiconductor module according to claim 19, wherein the IC chip includes a third surface extending between the first and second surfaces, and the resin adheres to at least a part of the third surface to extend monolithically from the first surface to the at least a part of the peripheral area.

21. A semiconductor module according to claim 17, wherein the second surface includes a peripheral area and a central area surrounded by the peripheral area, and the resin adheres to at least a part of the peripheral area and is prevented from adhering to the central area.

22. A semiconductor module according to claim 17, wherein the resin adheres to the whole of the second surface.

23. A semiconductor module according to claim 17, further comprising a casing receiving therein the IC chip and the resin, wherein the casing is fixed onto at least a part of the second surface while the resin is prevented from existing between the casing and the at least a part of the second surface.

24. A semiconductor module according to claim 17, wherein the resin is prevented from adhering to at least a part of the first surface.

25. A semiconductor module according to claim 17, further comprising a casing receiving therein the IC chip and the resin, wherein a modulus of longitudinal elasticity of the casing is smaller than a modulus of longitudinal elasticity of the resin.

26. A semiconductor module according to claim 1, wherein the IC chip includes first and second surfaces opposite to each other in a thickness direction of the IC chip, the first surface includes the terminal surface area, the part of the electrically conductive member extends along a part of the first surface, and a thickness of the resin on the second surface is not less than 10 μm and not more than a thickness of the IC chip.

27. A semiconductor module according to claim 17, wherein a thickness of the resin on the second surface is not less than 10 μm and not more than a thickness of the IC chip.

28. A semiconductor module according to claim 1, wherein a thickness of the semiconductor module is not more than 0.5 mm.

29. A semiconductor module according to claim 17, wherein a thickness of the semiconductor module is not more than 0.5 mm.

30. A semiconductor module according to claim 12, wherein the casing includes an adhesive layer adhering to the resin and a cover sheet adhered to the resin by the adhesive layer.

31. A semiconductor module according to claim 30, wherein the adhesive layer include nonwoven fabric.

32. A semiconductor module according to claim 17, further comprising a casing receiving therein the IC chip and the resin, wherein the casing includes an adhesive layer adhering to the resin and a cover sheet adhered to the resin by the adhesive layer.

33. A semiconductor module according to claim 32, wherein the adhesive layer include nonwoven fabric.

34. A method for producing a semiconductor module, comprising the steps of:
fixing an IC chip onto an electrically conductive member,
supplying a resin onto a joint portion between the IC chip and the electrically conductive member, and subsequently curing the resin,
removing a part of the electrically conductive member from the combined IC chip and electrically conductive member,
fixing an antenna coil onto a remainder part of the electrically conductive member of the combined IC chip and electrically conductive member, and
mounting the combined antenna coil, IC chip and electrically conductive member into a casing.

35. A method according to claim 34, wherein the mounting step includes:
arranging the combined antenna coil, IC chip and electrically conductive member between two nonwoven fabrics of a pair, and
arranging the pair of nonwoven fabrics between which the combined antenna coil, IC chip and electrically conductive member are arranged, between two cover sheets with an adhesive between each of the nonwoven fabrics and each of the two cover sheets facing to each other, and
compressing and heating the two cover sheets between which the pair of nonwoven fabrics is arranged, to adhere the cover sheets to the nonwoven fabrics through the adhesive.

36. A method according to claim 34, wherein the mounting step includes:
arranging the combined antenna coil, IC chip and electrically conductive member on a cover sheet with an adhesive between the combined antenna coil, IC chip and electrically conductive member and the cover sheet,
covering the combined antenna coil, IC chip and electrically conductive member on the cover sheet with another cover sheet to be arranged between the cover sheets, and
compressing and heating the cover sheets between which the combined antenna coil, IC chip and electrically conductive member are arranged, to adhere the cover sheets to each other and to the combined antenna coil, IC chip and electrically conductive member through the adhesive.

37. A method for producing a semiconductor module, comprising the steps of:
arranging an IC chip including an antenna coil and covered by a resin, between nonwoven fabrics of a pair, and
arranging the pair of nonwoven fabrics between which the IC chip is arranged, between two cover sheets with an adhesive between each of the nonwoven fabrics and each of the two cover sheets facing to each other, and
compressing and heating the two cover sheets between which the pair of nonwoven fabrics is arranged, to adhere the cover sheets to the nonwoven fabrics through the adhesive.

38. A method for producing a semiconductor module, comprising the steps of:
arranging an IC chip including an antenna coil and covered by a resin, on a cover sheet with an adhesive between the IC chip and the cover sheet,
covering the IC chip with another cover sheet to be arranged between the cover sheets, and
compressing and heating the cover sheets between which the IC chip is arranged, to adhere the cover sheets to each other and to the IC chip through the adhesive.

39. A semiconductor module according to claim 1, wherein the IC chip includes first and second surfaces opposite to each other in a thickness direction of the IC chip, the first surface includes the terminal surface area, the part of the electrically conductive member extends along a part of the first surface, and the resin adheres to the whole of a remainder part of the first surface other than the part of the first surface along which the part of the electrically conductive member extends.
